(19) United States
(12) Patent Application Publication
(10) Pub. No.: US 2021/0097769 A1
(43) Pub. Date: Apr. 1, 2021

(54) VIRTUAL REALITY VEHICLE TESTING

(71) Applicant: Ford Global Technologies, LLC, Dearborn, MI (US)

(72) Inventors: Turgay Isik Aslandere, Aachen (DE); Evangelos Bitsanis, Aachen/NRW (DE); Michael Marbaix, Whitby (CA); Frederic Stefan, Aachen (DE); Alain Marie Roger Chevalier, Henri-Chapelle (BE)

(73) Assignee: Ford Global Technologies, LLC, Dearborn, MI (US)

(21) Appl. No.: 17/036,372

(22) Filed: Sep. 29, 2020

(30) Foreign Application Priority Data
Sep. 30, 2019 (DE) 102019126401.4

(51) Int. Cl. G06T 19/00; G06T 15/00; G06F 30/22; G06F 30/15; G09B 23/10

(52) U.S. Cl. CPC G06T 19/006; G06T 15/005; G09B 23/10; G06F 30/15; G06F 30/22

(57) ABSTRACT

A computer includes a processor and a memory, the memory storing instructions executable by the processor to generate physics data representing operation of a virtual vehicle with a physics simulator processor, collect movement data of a user with a tracking processor, and provide, from a virtual reality processor, one or more images to a virtual reality display of the user based on the physics data sets and the collected movement data.

### CROSS-REFERENCE TO RELATED APPLICATIONS

This patent application claims priority to German Application No. 102019126401.4, filed Sep. 30, 2019, which is hereby incorporated herein by its reference in its entirety.

### BACKGROUND

The disclosure relates to a method for carrying out tests in a virtual environment. Furthermore, the disclosure relates to a computer program product and a system for carrying out such tests.

A self-driving motor vehicle is understood as a motor vehicle which can drive, steer, and park without the influence of a human driver (highly automated driving or autonomous driving). In the case in which no manual control is required on the part of the driver, the term robot automobile is also used. The driver seat can then remain empty; steering wheel, brake pedal, and accelerator pedal are possibly not present.

Such autonomous vehicles can perceive their environment with the aid of various sensors and can determine their own position and that of other road users from the acquired environmental data, set out for a destination in cooperation with the navigation software, and avoid collisions on the way there.

To test such automated driving, the motor vehicles are tested in the real world. However, this process is resource-intensive. To increase efficiency, tests in the computer-generated virtual environments, for example, tests in virtual cities, are necessary. VR technology (virtual reality technology) together with a virtual environment opens up many options. The main advantage of VR technology is that it permits test engineers to be part of the tests, to interact with the test scenario, or to interact with the configuration parameters.

Such virtual tests are presently carried out at a single location or in a laboratory at which the computers are located. Therefore, test engineers have to assemble at this location to be able to work together.

One of the most important requirements for the VR system is the real-time rendering and the simulation. If the number of the components in the virtual environment increases and thus the physical simulation becomes more complex, it is impossible to operate a virtual environment using a single workplace computer in real time. This is true in particular if the virtual reality elements, for example, tracking systems, use multiple displays for multiple users.

Methods for testing motor vehicles in a virtual environment are known from US 2015/0310758 A1, US 2017/0083794 A1, US 2017/0076019 A1, US 2017/0132118 A1, and CN 103592854 A.

There is thus a demand for showing ways in which multiple users at various locations can carry out such tests simultaneously in a virtual environment.

### SUMMARY

Disclosed is a method for carrying out tests in a virtual environment using a system designed as a distributed system having at least one node computer having a VR module, a tracking module, and a physics simulation module, having the following steps:
provision of a physics data set representative of a simulation by the physics simulation module,
provision of a tracking data set representative of the simulation by the tracking module, and
reading in and evaluation of the physics data set and the tracking data set to provide an image data set for the simulation by the VR module.

Using such a distributed system, a real concurrency can be implemented, i.e., multiple processes can be executed simultaneously.

In an example, a node computer can be associated with each user of a plurality of users of the system. The system can thus be scaled particularly easily and thus adapted to a plurality or an increasing number of users.

In another example, the tracking data set has data representative of the body and/or face and/or facial expression and/or gestures and/or speech of a user. A body and/or face of another user in the virtual environment can thus be visualized for another user. Furthermore, users can thus communicate with one another within the virtual environment by means of facial expression and/or gestures and/or speech.

Further disclosed is a computer program product and a system for carrying out such tests.

### BRIEF DESCRIPTION OF THE DRAWINGS

FIG. 1 shows a schematic illustration of components associated with a node of a testing system.

FIG. 2 shows the testing system having multiple node computers.

FIG. 3 shows a schematic illustration of a method.

### DETAILED DESCRIPTION

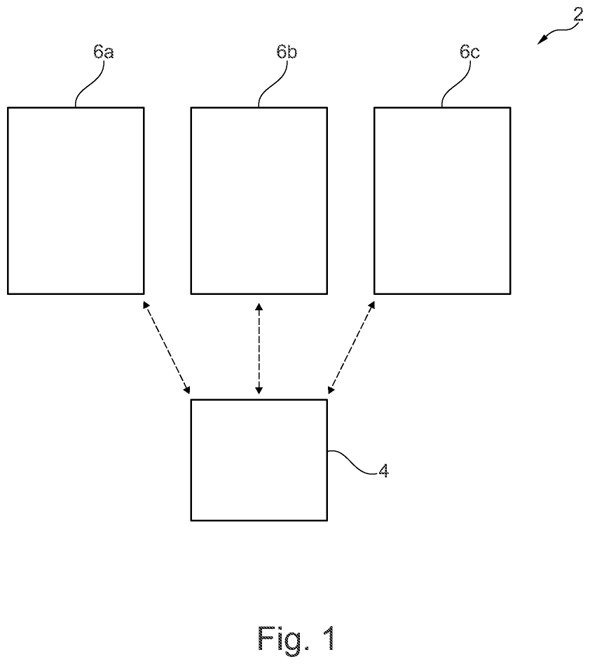

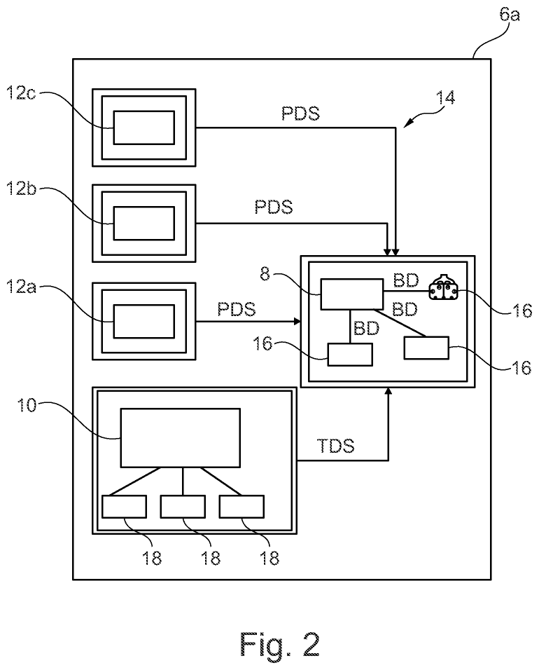

Reference is first made to FIGS. 1 and 2.

A system 2 is shown for carrying out tests, for example, for testing autonomous motor vehicles, in a virtual environment, for example, a virtual city.

The representation and simultaneous perception of reality and its physical properties in an interactive virtual environment computer generated in real time, is referred to as virtual reality, abbreviated VR.

Some requirements for a virtual environment are, e.g., immersion, plausibility, interactivity, and faithful reproduction.

Immersion describes the embedding of the user in the virtual environment. The perception of the user in the real world is reduced and the user feels more as a person in the virtual environment.

A virtual world is considered to be plausible by a user if the interaction in it is logical and consistent. This relates, on the one hand, to the feeling of the user that their own actions have an influence on the virtual environment, but also that the events in the environment influence the sense of the user, that they can thus act in the virtual world. The illusion is created by this interactivity that what appears to occur actually occurs.

Faithful reproduction is achieved if the virtual environment is designed accurately and faithful to nature. This occurs if the virtual world depicts properties of a natural world, it then appears believable to the user.

To generate the feeling of immersion, special output devices, for example, virtual reality headsets, are used to represent the virtual environment. To give a three-dimensional impression, two images from different perspectives are generated and displayed (stereo projection).

Special input devices are required for the interaction with the virtual world, for example, 3D mouse, data glove, or flystick, and also the unidirectional treadmill. The flystick is used for navigation with an optical tracking system, wherein infrared cameras permanently report the position in space to the VR system by acquiring markers on the flystick, so that the user can move freely without wiring. Optical tracking systems can also be used for acquiring tools and complete human models to be able to manipulate them within the VR scenario in real time.

Some input devices give the user force feedback on the hands or other body parts, so that the user can orient themselves by way of haptics and sensing as a further sensation in the three-dimensional world and can carry out realistic simulations.

Furthermore, software developed especially for this purpose is required for generating a virtual environment. The software has to be able to compute complex three-dimensional worlds in real time, i.e., at least 25 images per second, in stereo (separately for left and right eye of the user). This value varies depending on the application—a driving simulation, for example, can require at least 60 images per second to avoid nausea (simulator sickness).

Such a virtual environment becomes more and more complex the more components the simulation comprises and the more users interact simultaneously in the virtual environment with it and with one another. The demand for processing power rises accordingly, which rapidly exceeds the capacities of a single computer.

The system 2 is therefore designed as a distributed system. A distributed system is understood here as a combination of multiple independent computers, which present as a single system for the user or a distributed system is understood as a set of interacting processes or processors which do not have a shared memory and therefore communicate with one another via messages.

Using such a distributed system 2, a real concurrency can be implemented, i.e., multiple processes can really be executed simultaneously. In addition, such a distributed system 2 is better scalable than a single computer, since the performance of the distributed system 2 can be increased in a simple manner by adding further computers.

The system 2 shown in FIG. 1 is designed in the present example as a client-server system having a server 4 and three illustrated clients or node computers 6a, 6b, 6c, wherein each node computer 6a, 6b, 6c is associated with a different user of a plurality of users of the system 2. The data exchange can take place according to a network protocol, for example, UDP.

FIG. 2 shows the components of the system 2 which are associated with the node computer 6a.

These are a VR module 8, a tracking module 10, and a physics simulation module 12a, 12b, 12c, and also a network 14.

In this example, the system 2, the server 4, the VR module 8, the tracking module 10, and/or the physics simulation module 12a, 12b, 12c and also further components mentioned later can have hardware and/or software components for their respective tasks and functions.

Furthermore, each component can be in a different environment, for example, a computer, a workstation, or a CPU cluster.

The VR module 8 for providing the virtual environment uses a real-time rendering engine in the present example, which uses, for example, so-called Z buffering (also depth buffering or depth memory method). Using this method of computer graphics for coverage calculation, the three-dimensional surfaces visible to the user are determined in a computer graphic. The method establishes pixel by pixel by items of depth information in a so-called Z buffer which elements of a scene in the virtual environment have to be drawn from a user perspective and which are concealed. For example, the real-time rendering engine can use OpenGL® or DirectX®. Furthermore, the real-time rendering engine can be embedded in a game engine such as Unity® 3D or Unreal®. The VR module 8 is designed solely for a visualization and provides an image data set BD for this purpose—as will be further explained later.

The image data set BD can be output by means of various output devices 16, for example, by means of an HMD (Head-Mounted Display) or other projection-based systems, for example, Cave Automatic Virtual Environments (CAVEs).

The tracking module 10 collects and receives tracking data sets TDS from special input devices 18, which can acquire, for example, finger, head, and/or body movements of a user. The input devices 18 can include, e.g., Leap Motion®, HTC VIVE® sensors, Intel RealSense®, etc.

The tracking data sets TDS contain data representative of the position of the respective user and their body parts (fingers, head, and general body) in the real world and associate these data with the virtual world.

The tracking data sets TDS can also contain images of the user and components thereof. The persons, including their facial expressions and/or gestures, can thus be completely visualized in the virtual environment. In addition, speech recordings can be produced and played back, so that users can communicate with one another very naturally via speech. If a user wears an output device 18 designed as a head-mounted display, they would see that they are located on a virtual test site where autonomous motor vehicles are present, and they could see their body and their fingers. It is also possible to see reflections on a vehicle body. This increases the immersion and enables working together with the other users.

Furthermore, when the user assumes their place in the virtual environment, they can open virtual doors of the motor vehicle and/or stop or start autonomous driving functions using their virtual hand representation, for example, by pressing a virtual button. Furthermore, a user can navigate by means of predetermined gestures in the virtual environment. Furthermore, a user can effectuate a positioning of themselves in the virtual environment, for example, by means of a flystick. The virtual environment or traffic scenarios can be manipulated by the user by hand actions, i.e. a course of a road can be changed, or other road users, for example, pedestrians, can be placed differently. Finally, it can be provided that upon predetermined gestures, for example, thumbs up, a vehicle starts driving in the virtual environment and stops when the user looks away. Finally—if the virtual environment is a simulation of a real environment—a comparison with subsequent correction can be provided, in which a user wears a semi-translucent HMD during a trip with a real motor vehicle and the simulation is visualized in the context of an augmented reality application. For this purpose, the motor vehicle can have special hardware, for example, NVIDIA DRIVE PX.

The physics simulation module 12a, 12b, 12c provides the entire physical modeling in the form of a physics data set PDS, which is required by the VR module 8. Thus, for example, driving dynamics of a motor vehicle are simulated with the aid of Matlab®-Simulink® libraries using in-house software libraries. For this purpose, the physics simulation module 12a, 12b, 12c can have a physics engine such as Nvidia® PhysX® or Bullet Physics, for example, to calculate a collision between a user and a motor vehicle.

The physics simulation module 12a, 12b, 12c is embedded in a real-time computer environment, for example, a real-time operating system (for example, RTOS Linux®), so that the physics data set PDS can be sent with only minimal delay to the VR module 8.

The system 2 can have a plurality of physics simulation modules 12a, 12b, 12c. In the present example, there are three physics simulation modules 12a, 12b, 12c. In contrast, the processing load would be too large for a single physics simulation module 12a, 12b, 12c.

The physics simulation modules 12a, 12b, 12c are thus distributed onto various computer environments, for example, a laptop or a supercomputer. Each instance can carry out a separate physical calculation. Thus, for example, the physics simulation module 12a can simulate the aerodynamics of a motor vehicle, while the physics simulation module 12b can simulate a drivetrain of the motor vehicle.

The network 14 is not a component of the system 2, but rather a software library embedded in the components of the system 2. The main task of the network 14 is to ensure efficient communication between the components. The network 14 can use known network protocols such as UDP or TCP/IP.

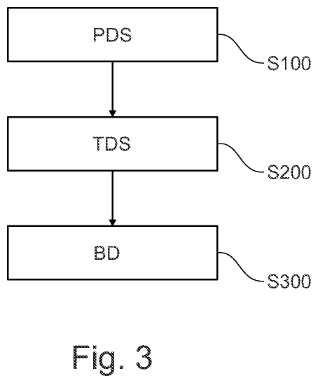

A method for carrying out tests in a virtual environment using the system 2 designed as a distributed system will now be explained with additional reference to FIG. 3.

In a first step S100, the physics simulation modules 12a, 12b, 12c each provide a physics data set PDS representative of the simulation.

In a further step S200, the tracking module 8 provides the tracking data set TDS representative of the simulation, which is based on data which were acquired using the respective input device 18.

In a further step S300, the VR module 8 reads in the physics data sets PDS and the tracking data sets TDS and evaluates them to provide the image data set BD for the simulation.

The image data set BD is then transferred to the output devices 16 to then be visualized to the respective user.

Notwithstanding the present example, the sequence of the steps can also be different. Furthermore, multiple steps can also be executed at the same time or simultaneously. Furthermore, notwithstanding the present example, individual steps can also be skipped or omitted.

Multiple users at various locations can thus carry out tests at the same time in a virtual environment.

### LIST OF REFERENCE SIGNS

2 system
4 server
6a node computer
6b node computer
6c node computer
8 VR module
10 tracking module
12a physics simulation module
12b physics simulation module
12c physics simulation module
14 network
16 output device
18 input device
BD image data set
PDS physics data set
TDS tracking data set
S100 step
S200 step
S300 step

1-7. (canceled)

8. A system, comprising a computer including a processor and a memory, the memory storing instructions executable by the processor to:
generate physics data representing operation of a virtual vehicle with a physics simulator processor;
collect movement data of a user with a tracking processor; and
provide, from a virtual reality processor, one or more images to a virtual reality display of the user based on the physics data sets and the collected movement data.

9. The system of claim 8, wherein the physic simulator processor, the tracking processor, and the virtual reality processor comprise a node of a distributed computing subsystem, and the instructions further include instructions to assign the node to the user.

10. The system of claim 9, wherein the instructions further include instructions to assign a respective one of a plurality of nodes to each of a plurality of users.

11. The system of claim 8, wherein the movement data includes data of at least one of a user's body, face, facial expression, gestures, or speech.

12. The system of claim 8, wherein the instructions further include instructions to generate a plurality of sets of physics data, each set of physics data generated by a respective physics simulator processor, each physics simulator processor simulating operation of a different virtual vehicle component.

13. The system of claim 8, wherein the instructions further include instructions to generate a plurality of sets of physics data, each set of physics data generated by a respective physics simulator processor in a node of a distributed computing subsystem, each set of physics data simulating operation of the virtual vehicle.

14. The system of claim 8, wherein the instructions further include instructions to adjust the physics data with the physics simulator processor based on the movement data of the user.

15. The system of claim 14, wherein the instructions further include instructions to adjust a location of a virtual component of the virtual vehicle based on the movement data of the user.

16. The system of claim 15, wherein the instructions further include instructions to provide, from the virtual reality processor, one or more images of the virtual component in the adjusted location to the virtual reality display.

17. The system of claim 8, wherein physics data include movement of the virtual vehicle and aerodynamic data of the virtual vehicle.

18. The system of claim 8, wherein the virtual reality display is a head-mounted display.

19. A method, comprising:
generating physics data representing operation of a virtual vehicle with a physics simulator processor;
collecting movement data of a user with a tracking processor; and
providing, from a virtual reality processor, one or more images to a virtual reality display of the user based on the physics data sets and the collected movement data.

20. The method of claim 19, wherein the physic simulator processor, the tracking processor, and the virtual reality display comprise a node, and the method further comprises assigning the node to the user.

21. The method of claim 20, further comprising assigning a respective one of a plurality of nodes to each of a plurality of users.

22. The method of claim 19, wherein the movement data includes data of at least one of a user's body, face, facial expression, gestures, or speech.

23. The method of claim 19, further comprising generating a plurality of sets of physics data, each set of physics data generated by a respective physics simulator processor, each physics simulator processor simulating operation of a different virtual vehicle component.

24. A distributed computing system comprising a plurality of nodes, each node comprising:
a physics simulator processor programmed to generate physics data of operation of a virtual vehicle;
a tracking processor programmed to collect movement data of a user; and
a virtual reality processor programmed to provide one or more images to a virtual reality display of the user based on the physics data and the movement data.

25. The system of claim 24, wherein the movement data includes data of at least one of a user's body, face, facial expression, gestures, or speech.

26. The system of claim 24, wherein each node further comprises a plurality of physics simulator processors, each physics simulator processor programmed to generate a respective set of physics data, each physics simulator processor simulating operation of a different virtual vehicle component.

27. The system of claim 24, wherein each node further comprises a plurality of physics simulator processors, each physics simulator processor programmed to generate a respective set of physics data, each set of physics data simulating operation of a same virtual vehicle component.
